(19) United States
(12) Patent Application Publication
(10) Pub. No.: US 2024/0107740 A1
(43) Pub. Date: Mar. 28, 2024

(54) SEMICONDUCTOR STRUCTURE AND METHOD FOR MANUFACTURING SAME

(71) Applicant: CHANGXIN MEMORY TECHNOLOGIES, INC., Hefei City, Anhui Province (CN)

(72) Inventor: Huihui GUI, Hefei (CN)

(21) Appl. No.: 18/531,765

(22) Filed: Dec. 7, 2023

Related U.S. Application Data
(63) Continuation of application No. PCT/CN23/70980, filed on Jan. 6, 2023.

(30) Foreign Application Priority Data
Sep. 15, 2022 (CN) 202211121602.3

(51) Int. Cl. H10B 12/00; H01L 23/00

(52) U.S. Cl. CPC H10B 12/02; H01L 24/08; H01L 24/80; H10B 12/315; H10B 12/482; H01L 2224/08145; H01L 2224/80013; H01L 2224/80895; H01L 2224/80896; H01L 2924/1436

(57) ABSTRACT

A method for manufacturing a semiconductor structure includes: forming first base which includes first substrate and active areas arranged in an array along first direction and second direction in first substrate, word lines being disposed in first base, extending along second direction and covering at least opposite sides of each active area; forming charge storage structures electrically connected with first ends of active areas on first base; forming second base which includes second substrate and bit lines disposed in second substrate, bit lines extending along first direction; connecting first base and second base by using a first surface of first base away from charge storage structures and a second surface of second base having structures of bit lines as connection surfaces, bit lines being electrically connected with second ends of active areas, and each first end being disposed opposite to a corresponding second end.

### CROSS-REFERENCE TO RELATED APPLICATION

The present application is a continuation application of International Patent Application No. PCT/CN2023/070980, filed on Jan. 6, 2023, which is based on and claims priority to Chinese Patent Application No. 202211121602.3, filed on Sep. 15, 2022 and entitled “SEMICONDUCTOR STRUCTURE AND METHOD FOR MANUFACTURING SAME”. The disclosures of International Patent Application No. PCT/CN2023/070980 and Chinese Patent Application No. 202211121602.3 are hereby incorporated by reference in their entireties.

### BACKGROUND

Semiconductor devices commonly used in electronic apparatuses such as computers, for example, dynamic random access memory (DRAM), are composed of multiple memory cells, and each of the memory cells usually includes a transistor and a capacitor. The gate of the transistor is electrically connected with a word line, the source of the transistor is electrically connected with a bit line, and the drain of the transistor is electrically connected with the capacitor. A word line voltage on the word line can control on and off of the transistor, so that data information stored in the capacitor can be read through the bit line, or data information can be written into the capacitor through the bit line.

At present, both bit lines and capacitors are on the same side of word lines in the mainstream structures of these semiconductor apparatuses. When manufacturing DRAM, the word lines are formed first, then the bit lines are formed, and finally the capacitors are formed. Because the bit lines and the capacitors are located on the same side of the word lines in the DRAM structure, the space on the same side of the word lines is crowded, which is not beneficial to the manufacturing of the bit lines and the capacitors, and increases the difficulty of the manufacturing process.

Therefore, how to reduce the difficulty of the manufacturing process is an urgent technical problem to be solved at present.

### SUMMARY

The disclosure relates to the technical field of integrated circuit, in particular to a semiconductor structure and a method for manufacturing the same.

A technical problem to be solved by the disclosure is to provide a semiconductor structure and a method for manufacturing the same, which can reduce difficulty of a manufacturing process.

In order to solve the above problem, the disclosure provide a method for manufacturing a semiconductor structure, which includes the following operations. A first base is formed. The first base includes a first substrate and active areas arranged in an array along a first direction and a second direction in the first substrate. Word lines are disposed in the first base, extend along the second direction and cover at least opposite sides of each of the active areas. Charge storage structures are formed on the first base, and are electrically connected with first ends of the active areas. A second base is formed. The second base includes a second substrate and bit lines disposed in the second substrate. The bit lines extend along the first direction. The first base and the second base are connected by using a first surface of the first base away from the charge storage structures and a second surface of the second base having structures of the bit lines as connection surfaces. The bit lines are electrically connected with second ends of the active areas, and each of the first ends is disposed opposite to a corresponding one of the second ends.

The embodiments of the disclosure also provide a semiconductor structure, including: a first base, word lines, charge storage structures and a second base. The first base includes a first substrate and active areas arranged in an array along a first direction and a second direction in the first substrate. The word lines are disposed in the first base, extend along the second direction and cover at least opposite sides of each of the active areas. The charge storage structures are disposed on the first base, and are electrically connected with first ends of the active areas. The second base is disposed on a surface of the first base away from the charge storage structures. The second base includes a second substrate and bit lines disposed in the second substrate. The bit lines extend along the first direction, and are electrically connected with second ends of the active areas, and each of the first ends is disposed opposite to a corresponding one of the second ends.

### BRIEF DESCRIPTION OF THE DRAWINGS

FIG. 1 is a flowchart of a method for manufacturing a semiconductor structure according to an embodiment of the disclosure.

FIG. 2A to FIG. 2F, FIG. 3A to FIG. 3F, FIG. 4A to FIG. 4F, FIG. 5A to FIG. 5F, FIG. 6A to FIG. 6F, FIG. 7A to FIG. 7F, FIG. 8A to FIG. 8F, FIG. 9A to FIG. 9F, FIG. 10A to FIG. 10F, FIG. 11A to FIG. 11F, FIG. 12A to FIG. 12F, FIG. 13A to FIG. 13F, FIG. 14A to FIG. 14F, FIG. 15A to FIG. 15F, FIG. 16A to FIG. 16F, FIG. 17A to FIG. 17F, FIG. 18A to FIG. 18F, and FIG. 19A to FIG. 19F are schematic diagrams of semiconductor structures formed by main operations of the manufacturing method according to the embodiments of the disclosure.

### DETAILED DESCRIPTION

Embodiments of the disclosure will be described in detail below in combination with the accompany drawings. In detailing the embodiments of the disclosure, for the sake of illustration, schematic diagrams will not be partially enlarged in accordance with the normal scale. The schematic diagrams are only exemplary, and should not limit the protection scope of the disclosure here. In addition, in actual manufacturing, the three-dimensional space dimensions of length, width and depth should be included. A semiconductor structure described in the embodiments of the disclosure may be, but not limited to, DRAM.

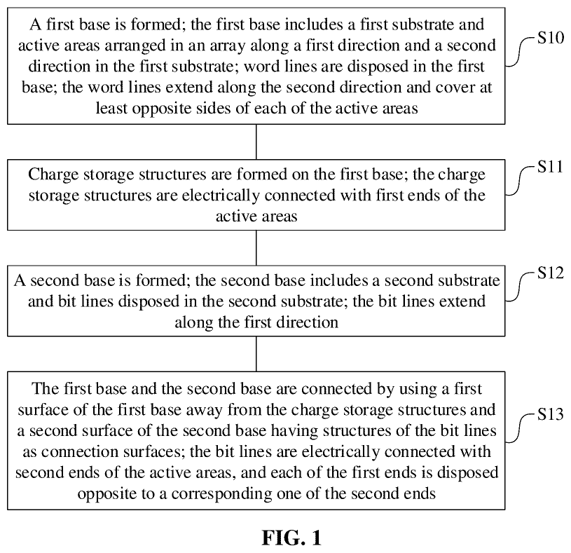

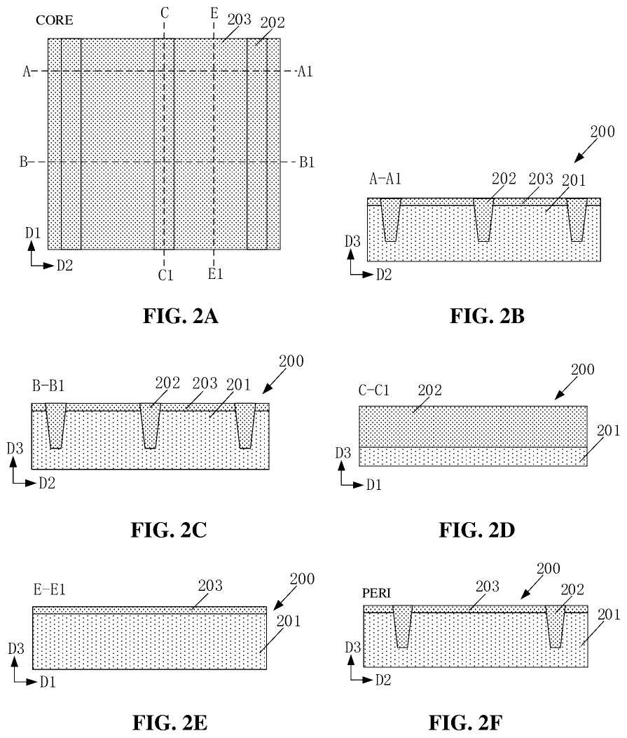

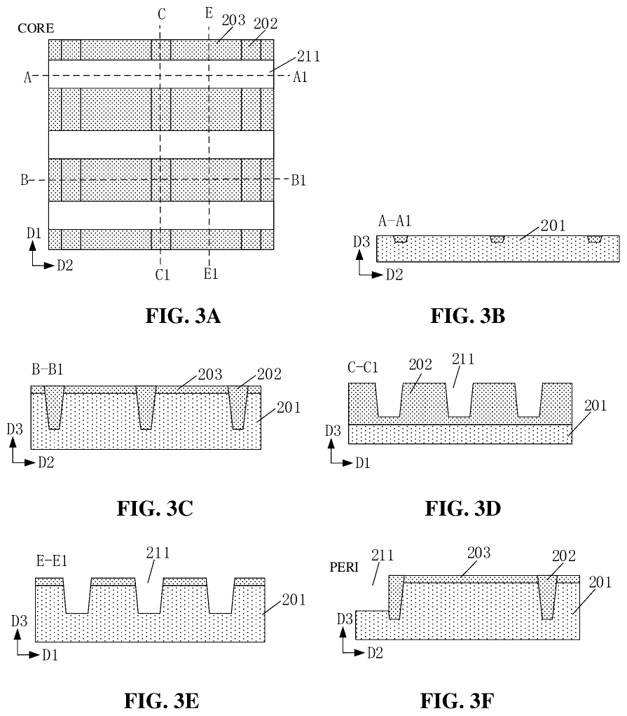

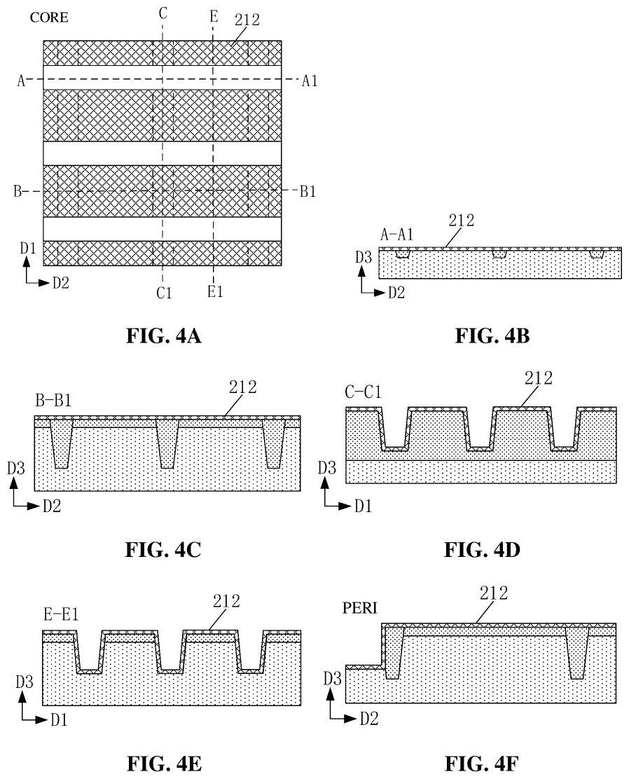

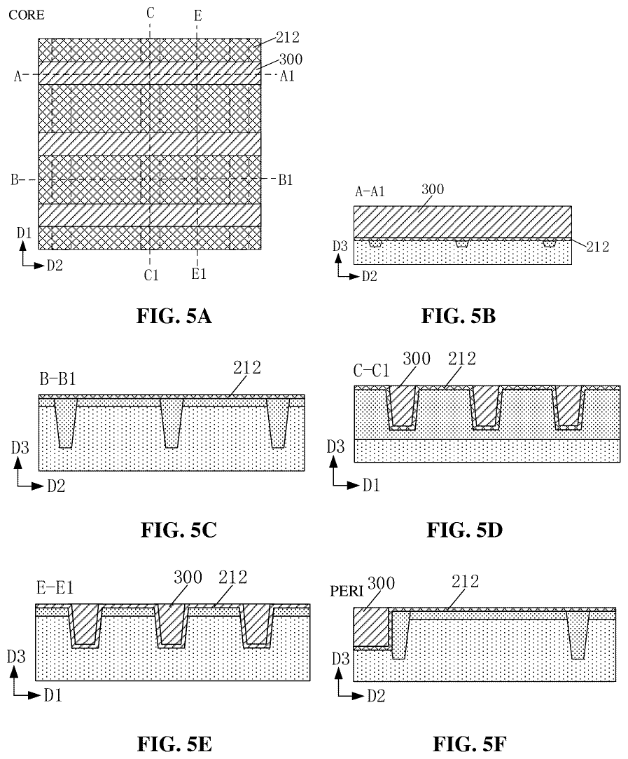

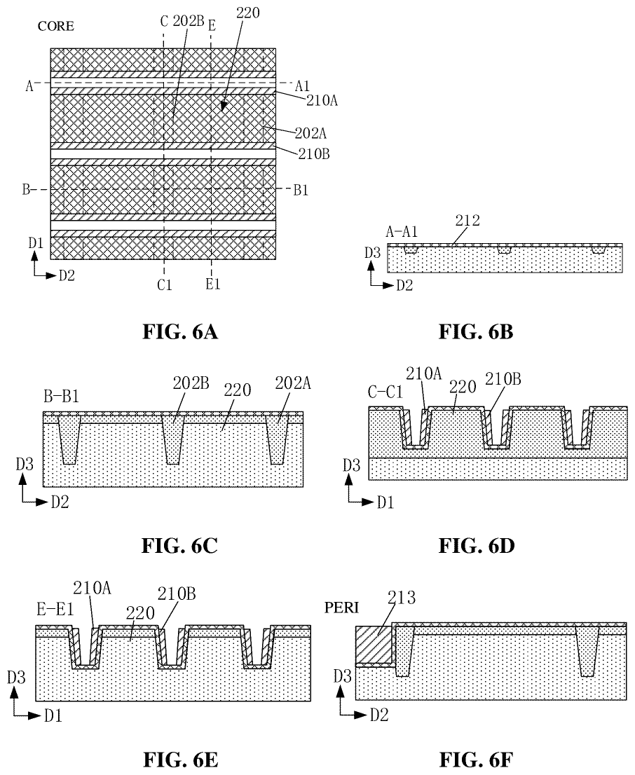

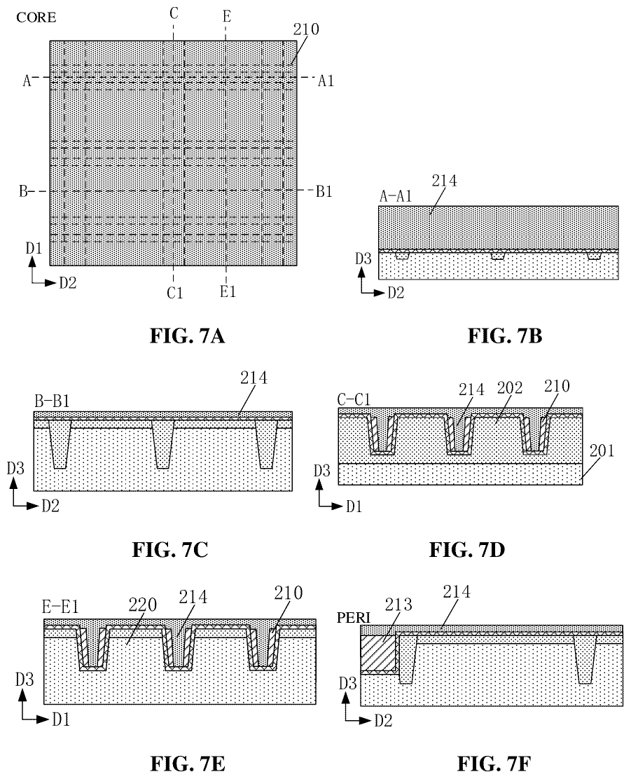

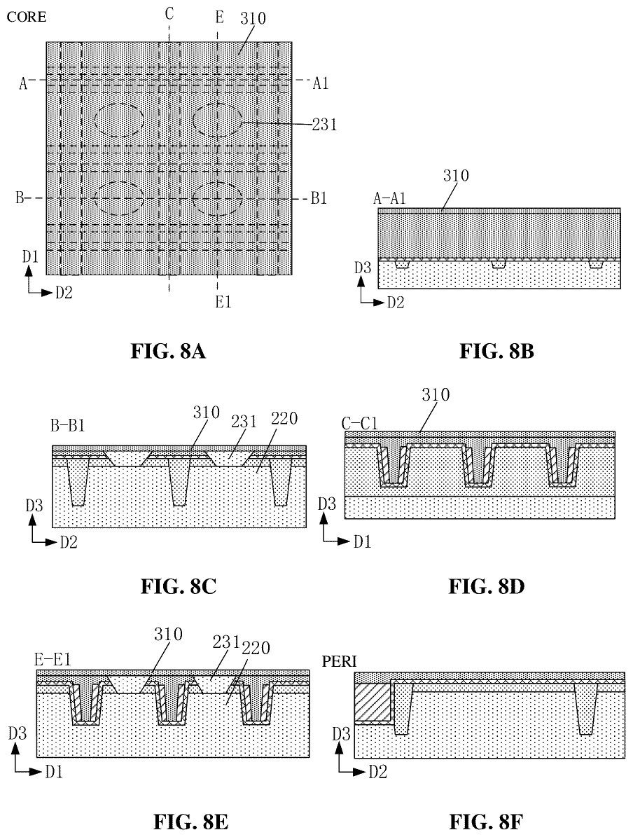

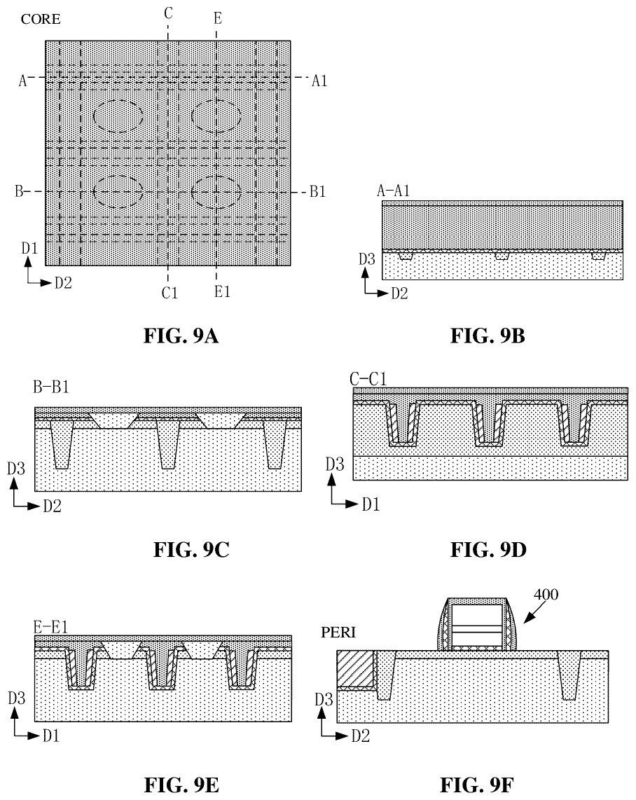

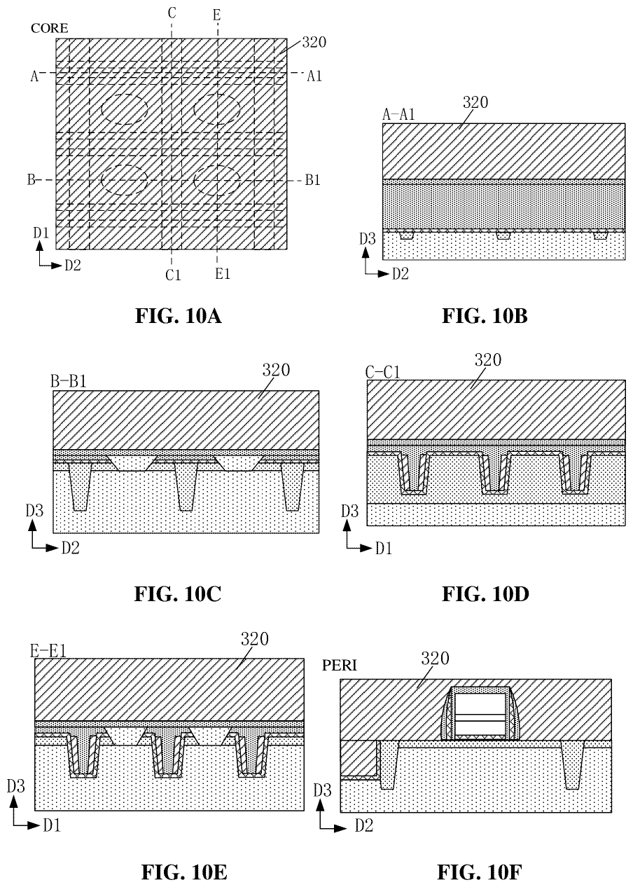

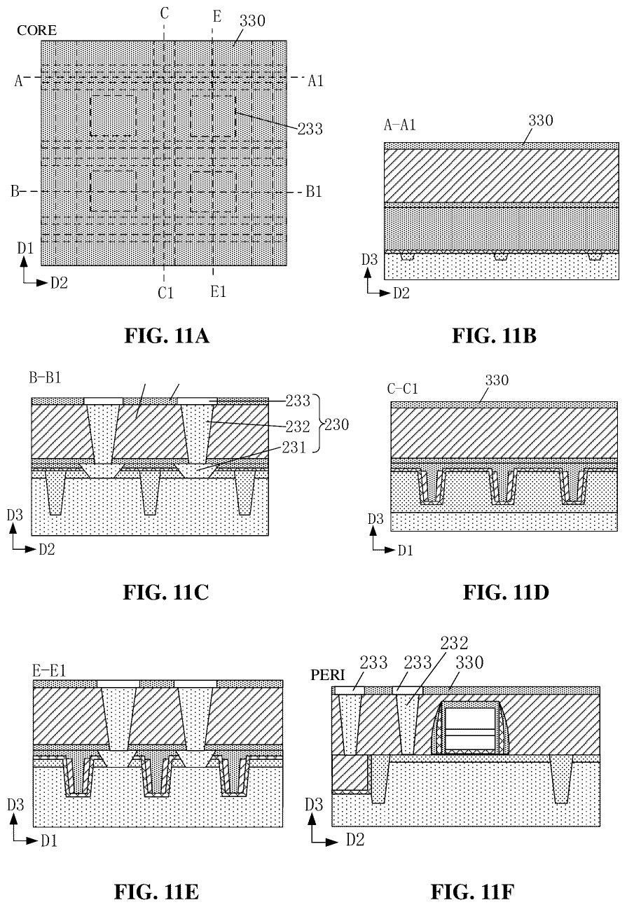

FIG. 1 is a flowchart of a method for manufacturing a semiconductor structure according to an embodiment of the disclosure. Referring to FIG. 1, the manufacturing method includes the following operations. In S10, a first base is formed. The first base includes a first substrate and active areas arranged in an array along a first direction and a second direction in the first substrate. Word lines are disposed in the first base, extend along the second direction and cover at least opposite sides of each of the active areas. In Si 1, charge storage structures are formed on the first base, and are electrically connected with first ends of the active areas. In S12, a second base is formed. The second base includes a second substrate and bit lines disposed in the second substrate. The bit lines extend along the first direction. In S13, the first base and the second base are connected by using a first surface of the first base away from the charge storage structures and a second surface of the second base having structures of the bit lines as connection surfaces. The bit lines are electrically connected with second ends of the active areas, and each of the first ends is disposed opposite to a corresponding one of the second ends.

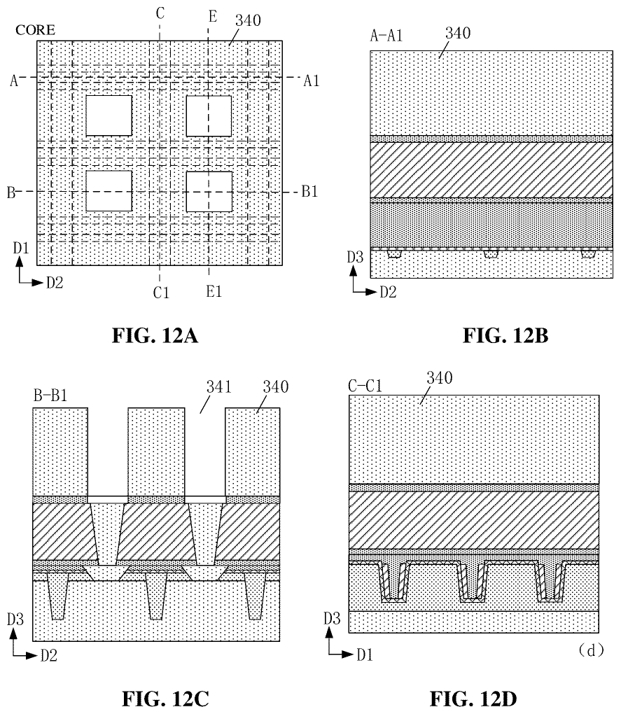

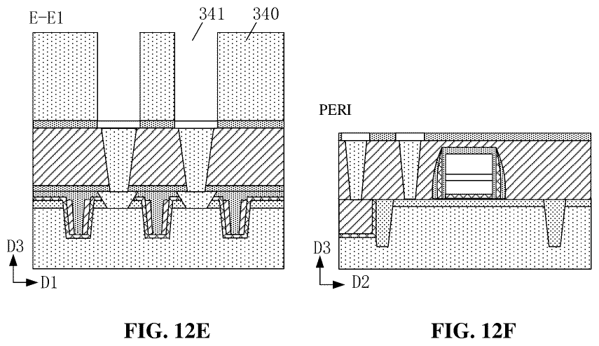

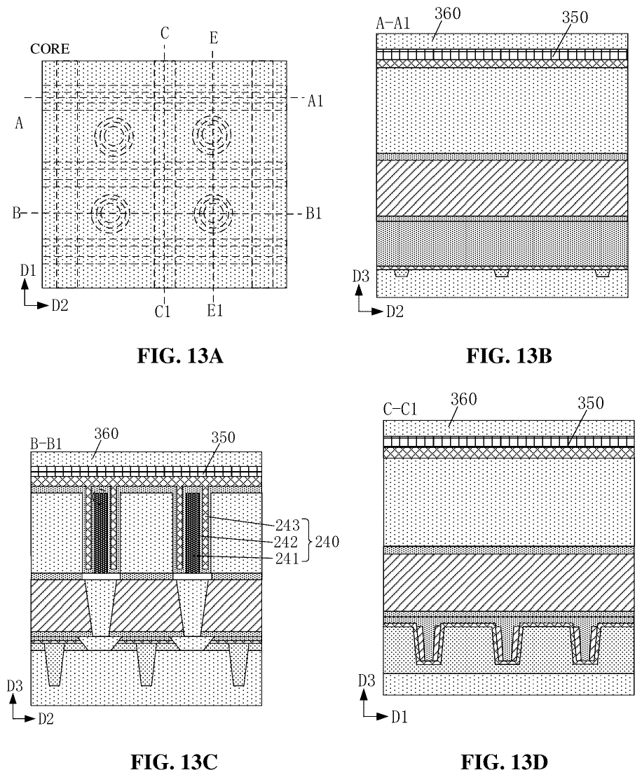

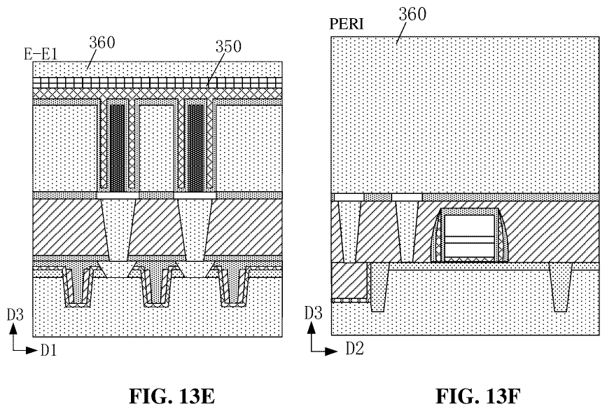

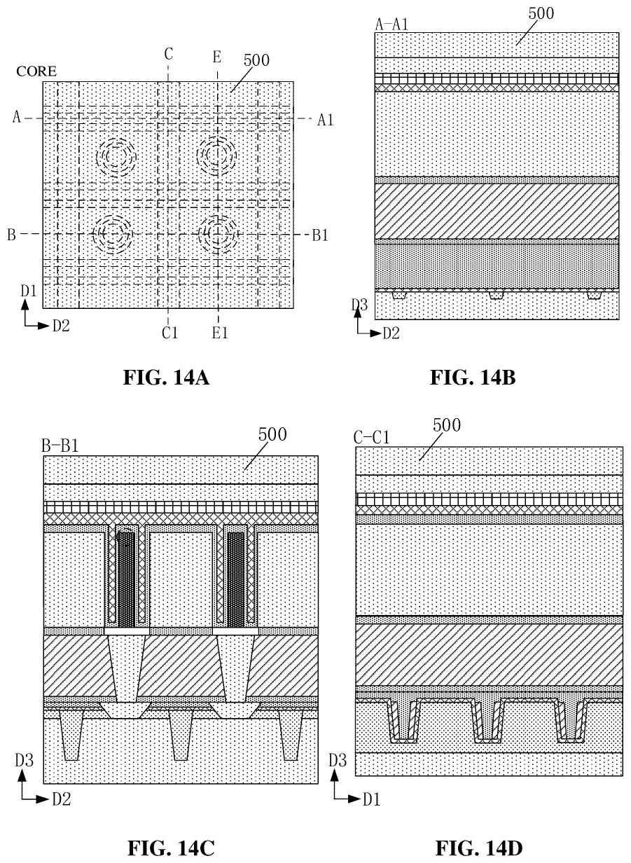

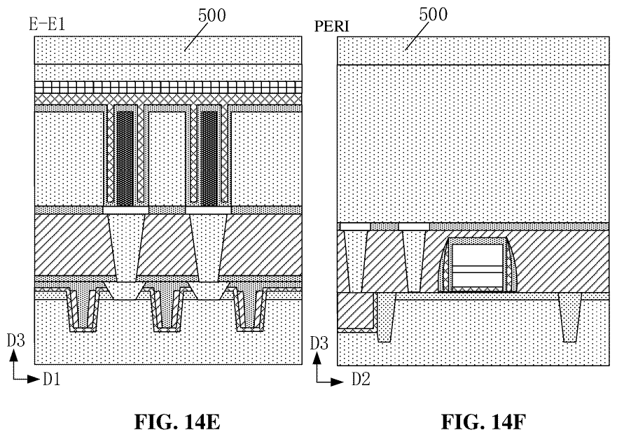

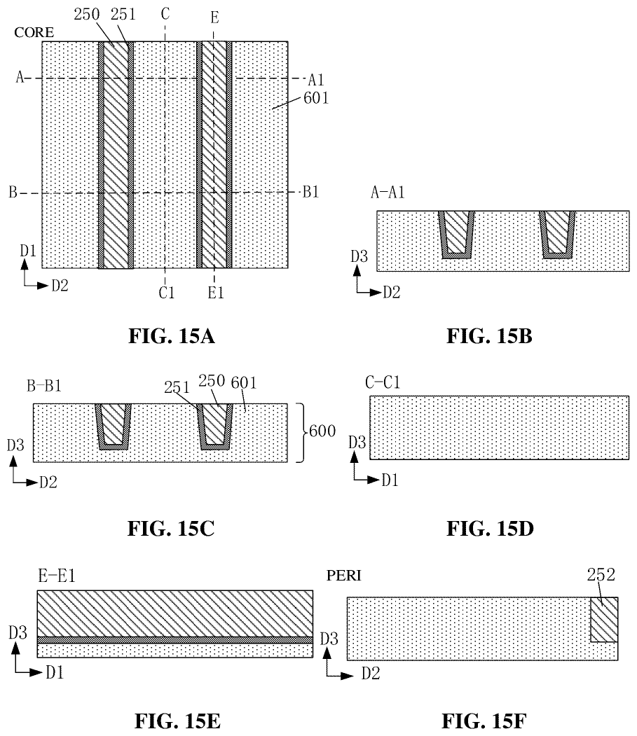

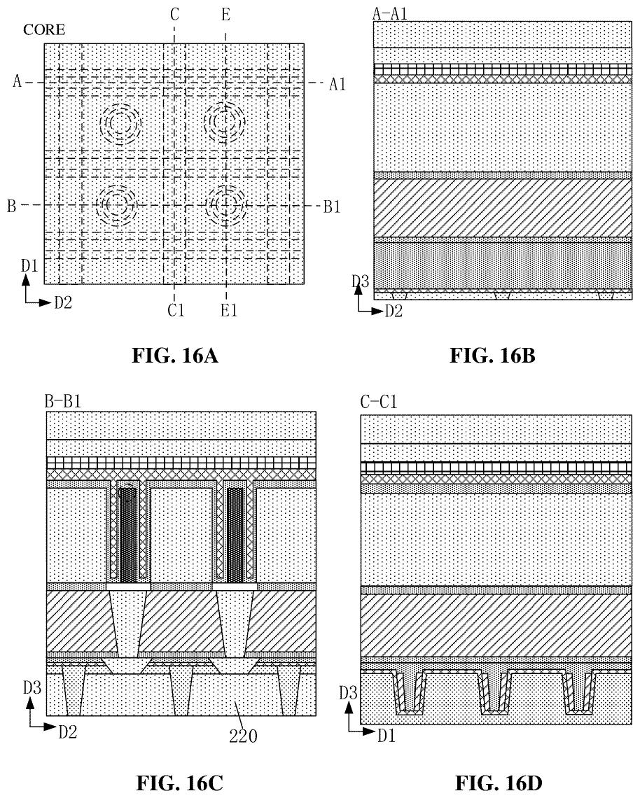

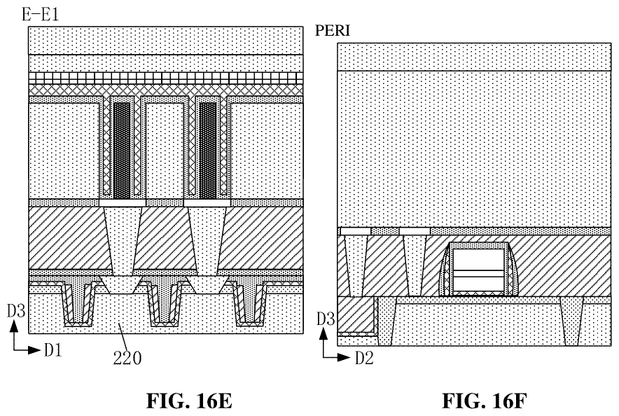

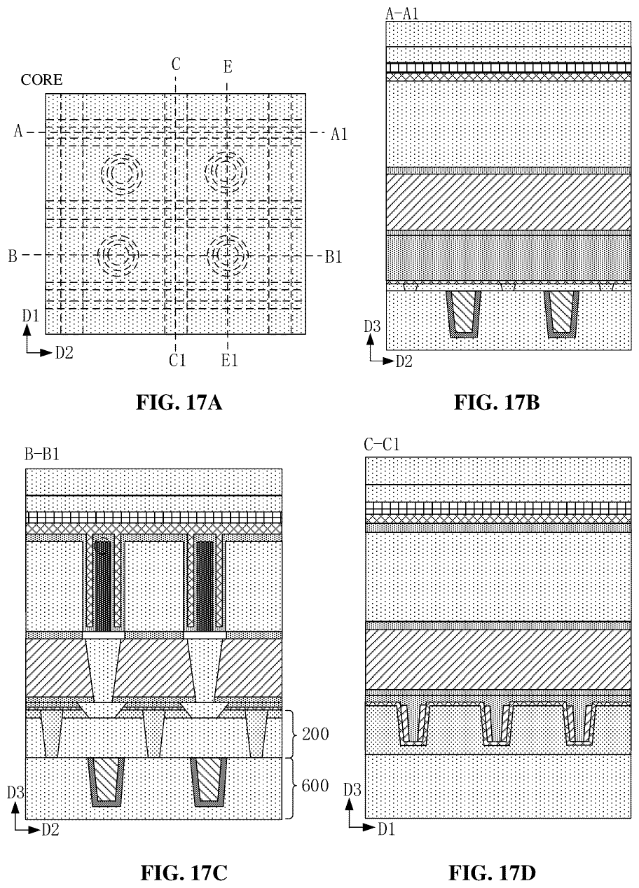

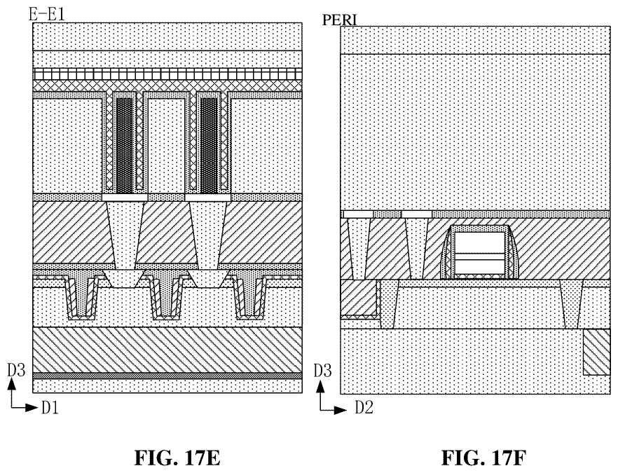

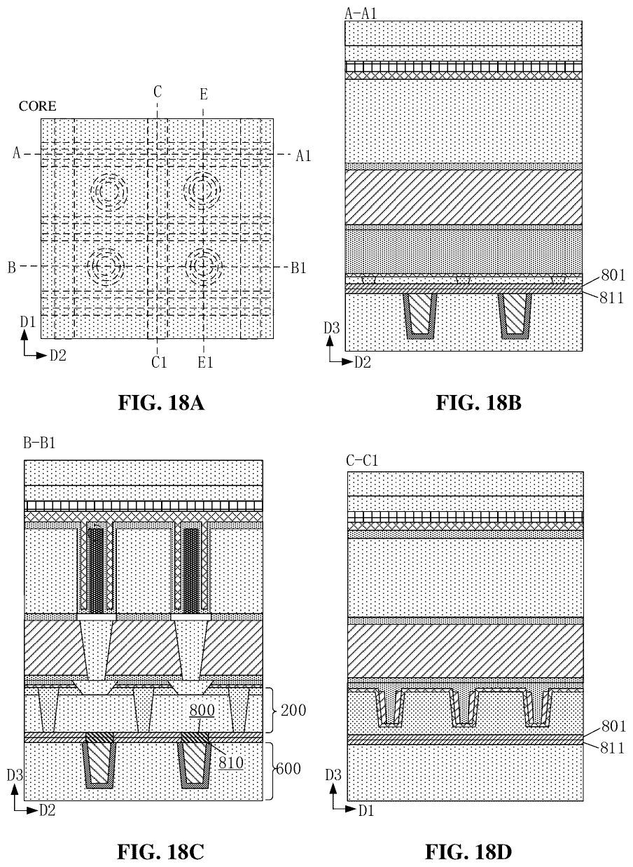

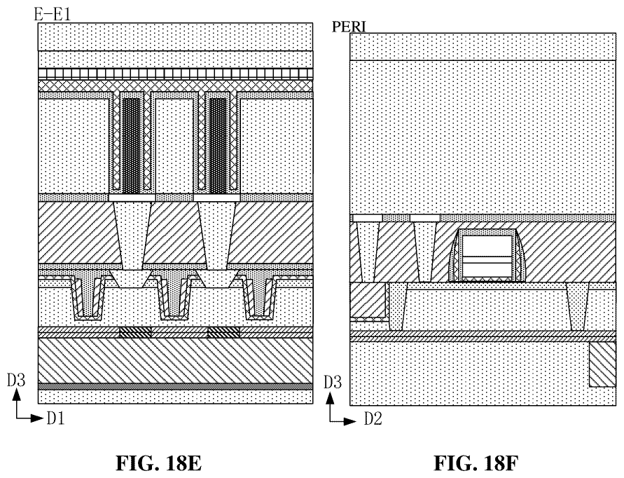

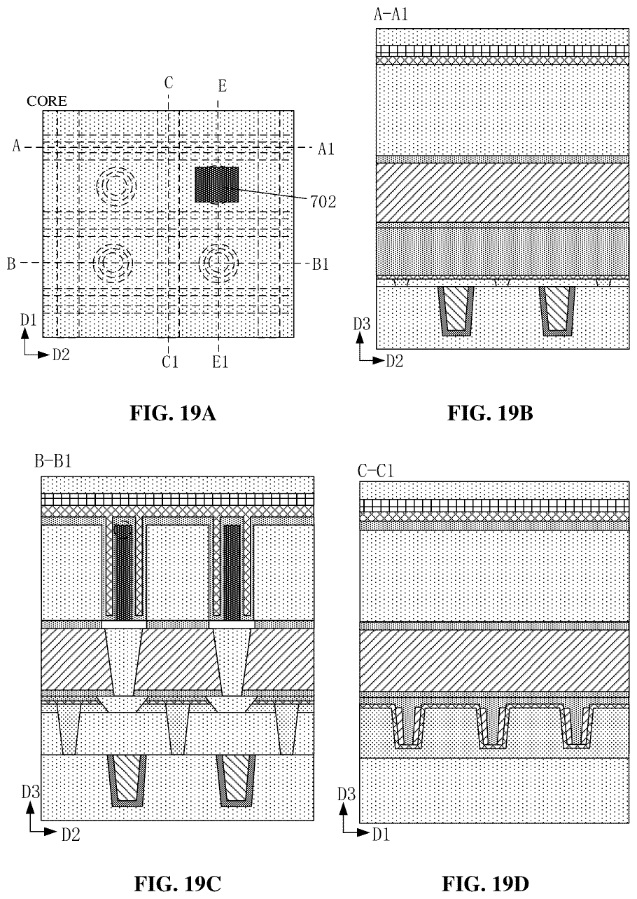

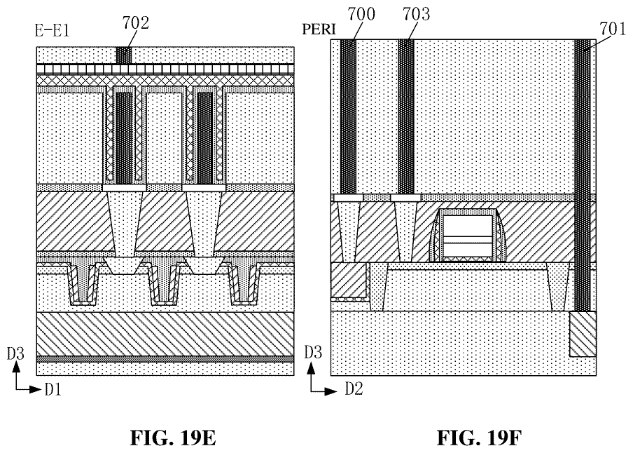

The method for manufacturing a semiconductor structure according to the embodiments of the disclosure is described in detail in combination with FIG. 1 to FIG. 19F. FIG. 2A to FIG. 19F are schematic diagrams showing semiconductor structures formed by main operations of the manufacturing method according to the embodiments of the disclosure. The semiconductor structure includes a core region (CORE) and a periphery region (PERI). A first direction D1 and a second direction D2 are parallel to a top surface of a first substrate 201 and intersect with each other, and a third direction D3 is perpendicular to the top surface of the first substrate 201. In the embodiments of the disclosure, the accompany drawings are explained by taking the first direction D1 as a Y-axis direction in a Cartesian coordinate system, the second direction D2 as a X-axis direction in the Cartesian coordinate system, and the third direction D3 as a Z-axis direction in the Cartesian coordinate system as an example.

Refer to FIG. 1 and FIG. 7A to FIG. 7F together, FIG. 7A is a top view of a core region CORE of a semiconductor structure; FIG. 7B is a cross-sectional schematic view along a line A-A1 in FIG. 7A; FIG. 7C is a cross-sectional schematic view along a line B-B1 in FIG. 7A; FIG. 7D is a cross-sectional schematic view along a line C-C1 in FIG. 7A; FIG. 7E is a cross-sectional schematic view along a line E-E1 in FIG. 7A; and FIG. 7F is a cross-sectional schematic view of a periphery region PERI of the semiconductor structure. In S10, a first base 200 is formed. The first base 200 includes a first substrate 201 and active areas 220 arranged in an array along the first direction D1 and the second direction D2 in the first substrate 201. Word lines 210 are disposed in the first base 200. The word lines 210 extend along the second direction D2 and cover at least opposite sides of each of the active areas 220.

In the embodiment, the word lines 210 cover the opposite sides of each of the active areas 220. In another embodiment, the word lines surround the active areas 220, i.e., form ring-gate structures. In this operation, the word lines 210 are formed in the core region CORE, and word line connection structures 213 are formed in the periphery region PERI. The word line connection structures 213 are connected with the word lines 210 for connecting the word lines 210 to other conductive structures.

As an example, an embodiment of the disclosure provides a method of forming the first base 200. Specifically, the method includes the following operations.

Referring to FIG. 2A to FIG. 2F, FIG. 2A is a top view of a core region CORE of a semiconductor structure; FIG. 2B is a cross-sectional schematic view along a line A-A1 in FIG. 2A; FIG. 2C is a cross-sectional schematic view along a line B-B1 in FIG. 2A; FIG. 2D is a cross-sectional schematic view along a line C-C1 in FIG. 2A; FIG. 2E is a cross-sectional schematic view along a line E-E1 in FIG. 2A; and FIG. 2F is a cross-sectional schematic view of a periphery region PERI of the semiconductor structure. The first substrate 201 is provided. Multiple isolation structures 202 arranged at intervals are formed in the first substrate 201. The isolation structure 202 extends along the first direction D1.

The first substrate 201 may include a silicon substrate, a germanium (Ge) substrate, a silicon germanium (SiGe) substrate, a silicon-on-insulator (SOI) substrate or a germanium-on-insulator (GOI) substrate, etc. The first substrate 201 may also be a substrate including other element semiconductors or compound semiconductors, such as gallium arsenide, indium phosphide, silicon carbide, etc. The first substrate 201 may also be a laminated structure, such as a silicon/germanium silicon laminated structure, etc. In addition, the first substrate 201 may be an ion-doped substrate, such as P-type doping or N-type doping. Multiple peripheral devices, such as field effect transistors, capacitors, inductors and/or diodes, may also be formed in the first substrate 201. In the embodiment, the first substrate 201 is a silicon substrate, which may include other device structures, such as transistor structures, metal wiring structures, etc., but are not depicted since they are irrelevant to the disclosure.

The multiple isolation structures 202 are arranged at intervals along the second direction D2, and each of the isolation structures 202 extends along the first direction D1. The first substrate 201 is also divided into multiple stripe structures by the isolation structures 202. In the embodiment, three isolation structures 202 are schematically depicted in the core region CORE and two isolation structures 202 are schematically depicted in the periphery region PERI.

In the embodiment, a surface of the first substrate 201 is also covered with a protective layer 203 for protecting the first substrate 201 during process operations. The isolation structures 202 penetrate the protective layer 203. The protective layer 203 may be an oxide layer, such as a silicon dioxide layer. In FIG. 2A, the isolation structures 202 are shielded by the protective layer 203. The isolation structures 202 are depicted with dotted lines in order to show the semiconductor structure of the embodiment of the disclosure clearly.

As an example, an embodiment of the disclosure provides a method for forming the isolation structures 202. The method includes the following operations. The protective layer 203 and a nitride layer are formed on the surface of the first substrate 201. Part of the protective layer 203, the nitride layer and the first substrate 201 are etched to form multiple shallow trenches extending along the first direction D1. The multiple shallow trenches are arranged at intervals along the second direction D2. An isolation material is deposited in the shallow trenches. The isolation material is etched back and the nitride layer is removed to form the isolation structures 202. Each of the isolation structures 202 includes, but is not limited to, an oxide layer, a nitride layer or a composite structure of an oxide layer and a nitride layer. In the embodiment, the isolation structure 202 is used as an example with only an oxide layer as an example, the oxide layer includes, but is not limited to, a silicon dioxide layer.

Referring to FIG. 3A to FIG. 3F, FIG. 3A is a top view of a core region CORE of a semiconductor structure; FIG. 3B is a cross-sectional schematic view along a line A-A1 in FIG. 3A; FIG. 3C is a cross-sectional schematic view along a line B-B1 in FIG. 3A; FIG. 3D is a cross-sectional schematic view along a line C-C1 in FIG. 3A; FIG. 3E is a cross-sectional schematic view along a line E-E1 in FIG. 3A; and FIG. 3F is a cross-sectional schematic view of a periphery region PERI of the semiconductor structure. Multiple word line trenches 211 arranged at intervals are formed in the first base 200. The word line trenches 211 extend along the second direction D2 and pass through the isolation structures 202. The multiple word line trenches 211 are arranged at intervals along the first direction D1. The word line trenches 211 are formed not only in the core region CORE, but also in the periphery region PERI.

In the operation, the word line trenches 211 may be formed by a photolithography and etching process. Specifically, a patterned mask layer is covered on a surface of the protective layer 203 and surfaces of the isolation structures 202. The mask layer shields areas that do not need to be etched and exposes areas that need to be etched. The protective layer 203, the isolation structures 202 and the substrate are etched by using the mask layer as a shield to form the word line trenches 211.

The word line trenches 211 and the isolation structures 202 intersect vertically, separate the first substrate 201 into multiple semiconductor pillars independent of each other. The semiconductor pillars serve as active areas of the semiconductor structure. In the embodiment, the word line trenches 211 are also formed in the periphery region PERI.

In some embodiments, after forming the word line trenches 211, an operation of forming a word line dielectric layer 212 is further included. Specifically, referring to FIG. 4A to FIG. 4F, FIG. 4A is a top view of a core region CORE of a semiconductor structure; FIG. 4B is a cross-sectional schematic view along a line A-A1 in FIG. 4A; FIG. 4C is a cross-sectional schematic view along a line B-B1 in FIG. 4A; FIG. 4D is a cross-sectional schematic view along a line C-C1 in FIG. 4A; FIG. 4E is a cross-sectional schematic view along a line E-E1 in FIG. 4A; and FIG. 4F is a cross-sectional schematic view of a periphery region PERI of the semiconductor structure. The word line dielectric layer 212 is formed within the word line trenches 211, the word line dielectric layer 212 covers sidewalls of the word line trenches 211. The isolation structures 202 are shielded by the word line dielectric layer 212 and are depicted by dotted lines. In the operation, the word line dielectric layer 212 may be formed by chemical vapor deposition (CVD), atomic layer deposition (ALD) or the like. A material of the word line dielectric layer 212 includes, but is not limited to, silicon dioxide, a high-K medium, etc. For example, in the embodiment, a silicon dioxide layer is deposited by an atomic layer deposition process, and the silicon dioxide layer is used as the word line dielectric layer 212. Inner walls of the word line trenches 211 of the core region CORE and the periphery region PERI are covered by the word line dielectric layer 212. It is to be understood that, the word line dielectric layer 212 only covers the inner walls of the word line trenches 211 and does not fill the word line trenches 211 completely, so as to leave enough space for forming word lines subsequently.

Referring to FIG. 5A to FIG. 5F, FIG. 5A is a top view of a core region CORE of a semiconductor structure; FIG. 5B is a cross-sectional schematic view along a line A-A1 in FIG. 5A; FIG. 5C is a cross-sectional schematic view along a line B-B1 in FIG. 5A; FIG. 5D is a cross-sectional schematic view along a line C-C1 in FIG. 5A; FIG. 5E is a cross-sectional schematic view along a line E-E1 in FIG. 5A; and FIG. 5F is a cross-sectional schematic view of a periphery region PERI of the semiconductor structure. A word line material 300 is filled in the word line trenches 211. In the embodiment, the word line material 300 includes titanium nitride (TiN) and metallic tungsten (W). In the operation, titanium nitride (TiN) and metallic tungsten (W) are deposited in the word line trenches 211 by using the atomic layer deposition process; and in order to clearly and concisely illustrate the technical solution of the embodiments of the disclosure, only one layer structure is schematically shown in the accompany drawings. The word line material 300 covers a surface of the word line dielectric layer 212 and fills the word line trenches 211.

Referring to FIG. 6A to FIG. 6F, FIG. 6A is a top view of a core region CORE of a semiconductor structure; FIG. 6B is a cross-sectional schematic view along a line A-A1 in FIG. 6A; FIG. 6C is a cross-sectional schematic view along a line B-B1 in FIG. 6A; FIG. 6D is a cross-sectional schematic view along a line C-C1 in FIG. 6A; FIG. 6E is a cross-sectional schematic view along a line E-E1 in FIG. 6A; and FIG. 6F is a cross-sectional schematic view of a periphery region PERI of the semiconductor structure. Part of the word line material 300 is removed, and the word line material 300 located on opposite sidewalls of each of the word line trenches 211 is retained to form two adjacent word lines 210. In the operation, part of the word line material 300 is etched back to a bottom of the word line trench 211 to form two relatively independent word lines 210 which are respectively disposed on the opposite sidewalls of the word line trench 211. Areas of the substrate bounded by the word lines 210 and the isolation structures 202 are the active areas 220. For example, referring to FIG. 6A to FIG. 6F, the word line material located between the adjacent two of the active areas 220 is etched to form two word lines, namely the word lines 210A and the word lines 210B. Areas of the first substrate 201 surrounded by the word lines 210A, the word lines 210B, the isolation structures 202A and the isolation structures 202B are the active areas 220. A word line 210A and a corresponding word line 210B together serve as a ring-gate of a corresponding active area 220. The active area 220 corresponding to the word line 210A and the word line 210B serve as a channel region of a transistor formed subsequently. In the operation, the word line material 300 in the periphery region PERI is etched to form word line connection structures 213.

Referring further to FIG. 7A to FIG. 7F, a first isolation layer 214 is formed between two adjacent word lines of the word lines 210. In the operation, an isolation material is deposited to form the first isolation layer 214, and the first isolation layer 214 also covers the surface of the first substrate 201. Since the isolation structures 202 and the word lines 210 are shielded by the first isolation layer 214, the isolation structures 202 and the word lines 210 are depicted by dotted lines in the accompany drawings. The first isolation layer 214 serves as an isolated insulating layer between the adjacent two of the word lines 210 to prevent conduction between the adjacent word lines 210 and influence on the performance of the semiconductor structure.

After the isolation material is deposited, a surface of the isolation material may be polished by a chemical mechanical polishing process (CMP) to obtain the first isolation layer 214 with a flat surface, which provides a good foundation for forming other semiconductor structures thereon, so as to reduce the process difficulty and improve the reliability of the semiconductor structure. The first isolation layer 214 includes, but is not limited to, a silicon nitride layer, a silicon oxynitride layer, etc.

In an embodiment, after forming the word lines 210 and before forming the charge storage structures 240, the manufacturing method further includes: forming capacitor connection structures 230 on the first base 200. The capacitor connection structures 230 are electrically connected with first ends of the active areas 220, respectively. The capacitor connection structure 230 includes a contact pad 231 and a conductive plug 232. The contact pad 231 is electrically connected with the first end of the active area 220 and the conductive plug 232 is electrically connected with the contact pad 231.

As an example, an embodiment of the disclosure provides a method of forming the capacitor connection structures 230. The method includes the following operations.

Referring to FIG. 8A to FIG. 8F, FIG. 8A is a top view of a core region CORE of a semiconductor structure; FIG. 8B is a cross-sectional schematic view along a line A-A1 in FIG. 8A; FIG. 8C is a cross-sectional schematic view along a line B-B1 in FIG. 8A; FIG. 8D is a cross-sectional schematic view along a line C-C1 in FIG. 8A; FIG. 8E is a cross-sectional schematic view along a line E-E1 in FIG. 8A; and FIG. 8F is a cross-sectional schematic view of a periphery region PERI of the semiconductor structure. The contact pads 231 are formed. The contact pads 231 are electrically connected with first ends of the active areas 220, respectively. The first end of the active area 220 refers to an end of the active area 220 facing a front face of the first base 200 along the third direction D3. In the operation, vias are formed by a photolithography and etching process. Each of the vias penetrates the first isolation layer 214, the word line dielectric layer 212 and the protective layer 203 to an active area 220. The via is filled with a conductive material to form a contact pad 231. The conductive material includes, but is not limited to, polysilicon.

After the contact pads 231 are formed, referring to FIG. 8A to FIG. 8F, a covering layer 310 is formed. The covering layer 310 only covers the surface of the semiconductor structure of the core region CORE and does not cover the surface of the semiconductor structure of the periphery region PERI, therefore the covering layer 310 protects the semiconductor structure of the core region CORE when peripheral gates 400 are subsequently formed in the periphery region PERI. The covering layer 310 includes, but is not limited to, a silicon nitride layer. In the accompany drawings, the contact pads 231 are shielded by the covering layer 310 and therefore the contact pads 231 are depicted by dotted lines.

Referring to FIG. 9A to FIG. 9F, FIG. 9A is a top view of a core region CORE of a semiconductor structure; FIG. 9B is a cross-sectional schematic view along a line A-A1 in FIG. 9A; FIG. 9C is a cross-sectional schematic view along a line B-B1 in FIG. 9A; FIG. 9D is a cross-sectional schematic view along a line C-C1 in FIG. 9A; FIG. 9E is a cross-sectional schematic view along a line E-E1 in FIG. 9A; and FIG. 9F is a cross-sectional schematic view of a periphery region PERI of the semiconductor structure. The peripheral gates 400 are formed in the periphery region PERI.

As an example, an embodiment of the disclosure provides a method for forming the peripheral gates 400. The method includes the following operations. The first isolation layer 214 in the periphery region PERI is removed to expose the word line dielectric layer 212. A polysilicon layer, a titanium nitride layer, a metallic tungsten layer and a silicon nitride layer are deposited on the word line dielectric layer 212. Parts of the polysilicon layer, the titanium nitride layer, the metallic tungsten layer and the silicon nitride layer are removed by a photolithography and etching process to form the gates. The gates correspond to active areas 220 of the periphery region PERI. Vertical walls are formed on sidewalls of the gates. In the operation of removing parts of the polysilicon layer, the titanium nitride layer, the metallic tungsten layer and the silicon nitride layer, the exposed word line dielectric layer 212 is also removed.

Referring to FIG. 10A to FIG. 10F, FIG. 10A is a top view of a core region CORE of a semiconductor structure; FIG. 10B is a cross-sectional schematic view along a line A-A1 in FIG. 10A; FIG. 10C is a cross-sectional schematic view along a line B-B1 in FIG. 10A; FIG. 10D is a cross-sectional schematic view along a line C-C1 in FIG. 10A; FIG. 10E is a cross-sectional schematic view along a line E-E1 in FIG. 10A; and FIG. 10F is a cross-sectional schematic view of a periphery region PERI of the semiconductor structure. A second interlayer dielectric layer 320 is formed. In the core region CORE, the second interlayer dielectric layer 320 covers the covering layer 310. In the periphery region PERI, the second interlayer dielectric layer 320 covers surfaces of the peripheral gates 400 and the surface of the first base 200. The surface of the first base 200 includes the first substrate 201 and other semiconductor structures (such as the word line connection structures 213, the protective layer 203, the isolation structures 202, etc.) exposed on the surface of the first substrate 201. In an embodiment, the second interlayer dielectric layer 320 may be formed by chemical vapor deposition or the like. The second interlayer dielectric layer 320 includes, but is not limited to, a boron and phosphorus doped silicon dioxide layer.

Referring to FIG. 11A to FIG. 11F, FIG. 11A is a top view of a core region CORE of a semiconductor structure; FIG. 11B is a cross-sectional schematic view along a line A-A1 in FIG. 11A; FIG. 11C is a cross-sectional schematic view along a line B-B1 in FIG. 11A; FIG. 11D is a cross-sectional schematic view along a line C-C1 in FIG. 11A; FIG. 11E is a cross-sectional schematic view along a line E-E1 in FIG. 11A; and FIG. 11F is a cross-sectional schematic view of a periphery region PERI of the semiconductor structure. After forming the second interlayer dielectric layer 320, the method includes the following operations.

Conductive plugs 232 are formed. Each of the conductive plugs 232 penetrates the second interlayer dielectric layer 320 and is electrically connected with a contact pad 231. In the operation, the second interlayer dielectric layer 320 is etched to form the vias. The vias expose the contact pads 231. The conductive material is filled in the vias to form the conductive plugs 232. Each of the conductive plugs 232 includes, but is not limited to, a composite layer of titanium nitride and metallic tungsten. In some embodiments, before filling the conductive material, the method further includes an operation for performing a cobalt treatment on a surface of each of the contact pads 231 to form a cobalt silicide layer (not shown in the accompany drawings). The conductive plugs 232 are formed in core region CORE and periphery region PERI. In the periphery region PERI, the conductive plugs 232 are connected with the word line connection structures 213 and the active areas 220 on the side of the peripheral gates 400. In an embodiment, the conductive plugs 232 also penetrate the covering layer 310 in the core region CORE.

After forming the conductive plugs 232, the manufacturing method further includes the following operations. A metal material is deposited on a surface of the second interlayer dielectric layer 320 and surfaces of the conductive plugs 232. The metal material is patterned to form connecting pads 233. The connecting pads 233 are connected with the conductive plugs 232. A third interlayer dielectric layer 330 is formed. The third interlayer dielectric layer 330 covers the upper surface of the second interlayer dielectric layer 320 and is filled between the adjacent connecting pads 233. In the embodiment, the third interlayer dielectric layer 330 may be formed by chemical vapor deposition or the like. The third interlayer dielectric layer 330 includes, but is not limited to, a silicon nitride layer.

In the core region CORE, the contact pads 231, the conductive plugs 232 and the connecting pads 233 together serve as the capacitor connection structures 230. In the periphery region PERI, the conductive plugs 232 and the connecting pads 233 together serve as peripheral connection structures.

Refer to FIG. 1 and FIG. 13A to FIG. 13F together, FIG. 13A is a top view of a core region CORE of a semiconductor structure; FIG. 13B is a cross-sectional schematic view along a line A-A1 in FIG. 13A; FIG. 13C is a cross-sectional schematic view along a line B-B1 in FIG. 13A; FIG. 13D is a cross-sectional schematic view along a line C-C1 in FIG. 13A; FIG. 13E is a cross-sectional schematic view along a line E-E1 in FIG. 13A; and FIG. 13F is a cross-sectional schematic view of a periphery region PERI of the semiconductor structure. In S11, charge storage structures 240 are formed on the first base 200. The charge storage structures 240 are electrically connected with first ends of the active areas 220, respectively. In an embodiment, the charge storage structures 240 are formed on the third interlayer dielectric layer 330 after the capacitor connection structures 230 are formed.

In an embodiment, the charge storage structures are capacitor structures. Each of the charge storage structures 240 includes a lower electrode 241, a capacitor dielectric layer 242 and an upper electrode 243. The lower electrode 241 is electrically connected with a corresponding one of the capacitor connection structures 230. The capacitor dielectric layer 242 covers a surface of the lower electrode 241. The upper electrode 243 covers a surface of the capacitor dielectric layer 242. In another embodiment, the charge storage structures may also include magnetic storage elements.

As an example, an embodiment of the disclosure provides a method for forming the charge storage structures 240. The method includes the following operations. Referring to FIG. 12A to FIG. 12F, FIG. 12A is a top view of a core region CORE of a semiconductor structure; FIG. 12B is a cross-sectional schematic view along a line A-A1 in FIG. 12A; FIG. 12C is a cross-sectional schematic view along a line B-B1 in FIG. 12A; FIG. 12D is a cross-sectional schematic view along a line C-C1 in FIG. 12A; FIG. 12E is a cross-sectional schematic view along a line E-E1 in FIG. 12A; and FIG. 12F is a cross-sectional schematic view of a periphery region PERI of the semiconductor structure. An interlayer supporting layer 340 is formed, and capacitor holes 341 are formed. The capacitor holes 341 penetrate the interlayer supporting layer 340 to the capacitor connection structures 230.

In an embodiment, the interlayer supporting layer 340 is formed on a surface of the third interlayer dielectric layer 330. The interlayer supporting layer 340 may include a bottom supporting layer, a middle supporting layer and a top supporting layer for supporting the charge storage structures 240. In the embodiment, only one layer of the supporting layers is schematically depicted. The specific structure of the interlayer supporting layer 340 is not repeated here.

In the operation, the capacitor holes 341 are formed by a photolithography and etching process. The capacitor holes 341 penetrate the interlayer supporting layer 340 and expose the connecting pads 233.

Referring further to FIG. 13A to FIG. 13F, a lower electrode 241 is formed in each of the capacitor holes 341. The lower electrode 241 is connected with a corresponding one of the capacitor connection structures 230. A sidewall of the lower electrode 241 is spaced from a sidewall of the capacitor hole 341. A capacitor dielectric layer 242 is formed on the sidewall of the lower electrode 241 and the sidewall of the capacitor hole 341. An upper electrode 243 is formed. The upper electrode 243 covers a surface of the capacitor dielectric layer 242.

In the operation, a titanium nitride material layer may be deposited by a chemical vapor deposition process, an atomic layer deposition process, etc. The titanium nitride material layer is etched back to form a pillar for each of the lower electrodes 241. The sidewall of the lower electrode 241 pillar is spaced from the sidewall of the capacitor hole 341, for forming the capacitor dielectric layer 242 and the upper electrode 243. The capacitor dielectric layer 242 may be a high K dielectric layer and the upper electrode 243 may be a titanium nitride layer.

Referring further to FIG. 13A to FIG. 13F, in an embodiment, after the charge storage structures 240 are formed, the following operation is further included. A silicon germanium layer 350 covering a surface of each of the charge storage structures 240 is formed. In the embodiment, the silicon germanium layer 350 covers a surface of each of the upper electrodes 243. After the silicon germanium layer 350 is formed, a first interlayer dielectric layer 360 is formed. The first interlayer dielectric layer 360 covers a surface of the silicon germanium layer 350 for protecting the charge storage structures 240. In the periphery region PERI, no silicon germanium layer 350 is formed, and the first interlayer dielectric layer 360 covers the surfaces of the connecting pads 233 and the surface of the third interlayer dielectric layer 330. The first interlayer dielectric layer 360 may be a single-layer structure or a multi-layer composite structure. For example, in an embodiment, the first interlayer dielectric layer 360 is a single-layer silicon dioxide. In another embodiment, the first interlayer dielectric layer 360 is a composite structure of a silicon dioxide layer and a silicon nitride layer.

After forming the first interlayer dielectric layer 360, the following operation is further included. A third base 500 is provided. The first base 200 and the third base 500 are connected by using one surface of the first base 200 having the charge storage structures 240 as a connection surface. Specifically, in an embodiment, referring to FIG. 14A to FIG. 14F, FIG. 14A is a top view of a core region CORE of a semiconductor structure; FIG. 14B is a cross-sectional schematic view along a line A-A1 in FIG. 14A; FIG. 14C is a cross-sectional schematic view along a line B-B1 in FIG. 14A; FIG. 14D is a cross-sectional schematic view along a line C-C1 in FIG. 14A; FIG. 14E is a cross-sectional schematic view along a line E-E1 in FIG. 14A; and FIG. 14F is a cross-sectional schematic view of a periphery region PERI of the semiconductor structure. The third base 500 is provided. The third base 500 is connected with the first base 200 by using the first interlayer dielectric layer 360 as a connection surface. A surface of the third base 500 may be connected with the first interlayer dielectric layer 360 by using a bonding process. The third base 500 is used for supporting the first base 200 and protecting the semiconductor structure in the first base 200 during subsequent processes. The third base 500 may include a silicon substrate, a germanium (Ge) substrate, a silicon germanium (SiGe) substrate, an SOI substrate or a GOI substrate, etc. In the embodiment, the third base 500 is a silicon substrate.

Refer to FIG. 1 and FIG. 15A to FIG. 15F together, FIG. 15A is a top view of a core region CORE of a semiconductor structure; FIG. 15B is a cross-sectional schematic view along a line A-A1 in FIG. 15A; FIG. 15C is a cross-sectional schematic view along a line B-B1 in FIG. 15A; FIG. 15D is a cross-sectional schematic view along a line C-C1 in FIG. 15A; FIG. 15E is a cross-sectional schematic view along a line E-E1 in FIG. 15A; and FIG. 15F is a cross-sectional schematic view of a periphery region PERI of the semiconductor structure. In S12, a second base 600 is formed. The second base 600 includes a second substrate 601 and multiple bit lines 250 arranged at intervals in the second substrate 601. The bit lines 250 extend along the first direction D1. In the operation, surfaces of the bit lines 250 are exposed on a surface of the second substrate 601 to facilitate subsequent connection with the active areas 220.

The second substrate 601 may include a silicon substrate, a germanium (Ge) substrate, a silicon germanium (SiGe) substrate, an SOI substrate or a GOI substrate, etc. The second substrate 601 may also be a substrate including other element semiconductors or compound semiconductors, such as gallium arsenide, indium phosphide, silicon carbide, etc. The second substrate 601 may also be a laminated structure, such as a silicon/germanium silicon laminated structure, etc. In addition, the second substrate 601 may be an ion-doped substrate, such as P-type doping or N-type doping. Multiple peripheral devices, such as field effect transistors, capacitors, inductors and/or diodes, may also be formed in the second substrate 601. In an embodiment, the second substrate 601 is a silicon substrate, which may include other device structures, such as transistor structures, metal wiring structures, etc., but are not depicted since they are irrelevant to the disclosure.

The multiple bit lines 250 are arranged at intervals along the second direction D2. Locations of the bit lines 250 correspond to locations of the active areas 220 in the first base 200. A second isolation layer 251 is provided between each of the bit lines 250 and the second substrate 601. The second isolation layer 251 includes, but is not limited to, an oxide layer. The bit line 250 includes, but is not limited to, a composite layer of titanium nitride and metallic tungsten.

The second base 600 also includes a core region CORE and a periphery region PERI. In the operation, the bit lines 250 are formed in the core region CORE and the bit line connection structures 252 are formed in the periphery region PERI.

As an example, an embodiment of the disclosure provides a method for forming the bit lines 250. The method includes: forming bit line trenches (not shown in the accompany drawings) in the second substrate 601. The bit line trenches are located not only in the core region CORE but also in the periphery region PERI. A second isolation layer 251 covering an inner wall of each of the bit line trenches is formed in the bit line trench. A bit line 250 is formed in each of the bit line trenches in the core region CORE. A bit line connection structure 252 is formed in each of the bit line trenches in the periphery region PERI. A second isolation layer 251 is disposed between the bit line 250 and the second substrate 601, and between the bit line connection structure 252 and the second substrate 601.

Referring to FIG. 16A to FIG. 16F, FIG. 16A is a top view of a core region CORE of a semiconductor structure; FIG. 16B is a cross-sectional schematic view along a line A-A1 in FIG. 16A; FIG. 16C is a cross-sectional schematic view along a line B-B1 in FIG. 16A; FIG. 16D is a cross-sectional schematic view along a line C-C1 in FIG. 16A; FIG. 16E is a cross-sectional schematic view along a line E-E1 in FIG. 16A; and FIG. 16F is a cross-sectional schematic view of a periphery region PERI of the semiconductor structure. Since the active areas 220 are not exposed from a back face of the first base 200, in the operation, the first substrate 201 on a surface of the first base 200 away from the charge storage structures 240 is thinned, to expose second ends of the active areas 220 to connect with bit lines 250. The second end is an end of the active area 220 facing a front face of the second base 600 along the third direction D3, and the first end is disposed opposite to the second end. In the operation, the method for thinning the first substrate 201 includes, but is not limited to, a chemical mechanical polishing process. It is to be understood that in order to avoid the word lines 210 being connected with the bit lines 250, the word lines 210 are not exposed in this operation.

Referring to FIG. 17A to FIG. 17F, FIG. 17A is a top view of a core region CORE of a semiconductor structure; FIG. 17B is a cross-sectional schematic view along a line A-A1 in FIG. 17A; FIG. 17C is a cross-sectional schematic view along a line B-B1 in FIG. 17A; FIG. 17D is a cross-sectional schematic view along a line C-C1 in FIG. 17A; FIG. 17E is a cross-sectional schematic view along a line E-E1 in FIG. 17A; and FIG. 17F is a cross-sectional schematic view of a periphery region PERI of the semiconductor structure. In S13, the first base 200 and the second base 600 are connected by using a first surface of the first base 200 away from the charge storage structures 240 and a second surface of the second base 600 having structures of the bit lines 250 as connection surfaces. The bit lines 250 are electrically connected with the second ends of the active areas 220, and each of the first ends is disposed opposite to a corresponding one of the second ends.

In an embodiment, the first base 200 is connected with the second base 600 by a bonding process. Specifically, the first base 200 and the second base 600 are connected by using the bonding process with a thinned surface of the first base 220 as the first surface, a surface of the second base 600 exposing the bit lines 250 as the second surface, and the first surface and the second surface as bonding interfaces.

As an example, an embodiment of the disclosure provides a bonding method.

Before the operation of performing the bonding process, a plasma treatment is performed on the first surface of the first base 200 and the second surface of the second base 600, so as to activate the first surface and the second surface in preparation for bonding. The plasma treatment may include any one of a nitrogen plasma treatment, an argon plasma treatment, a neon plasma treatment. The plasma treatment may increase dangling bonds on the first surface and the second surface, such as Si-dangling bonds. The more dangling bonds are on the first surface and the second surface, the greater the surface energy is, and the greater the bonding strength is and the firmer the bonding between the first surface and the second surface is during the subsequent bonding.

A hydrophilic treatment is performed on the first surface of the first base 200 and the second surface of the second base 600 to form O—H bonds on the first surface and the second surface. O—H bonds may be combined with Si-dangling bonds to form Si—O—H bonds. The Si—O—H bonds have strong adsorption, and the bonding strength between the first surface and the second surface is greater through the Si—O—H bonds. In some embodiments, when the plasma treatment is performed on the first surface of the first base 200 and the second surface of the second base 600, a certain amount of water may be introduced. The water may be ionized to form hydroxyl groups, which combine with the Si-dangling bonds to form the Si—O—H bonds. In other embodiments, the hydrophilic treatment may be performed after the plasma treatment. For example, the first surface and the second surface may be respectively cleaned with a chemical cleaning solution. On one hand, impurities on the first surface and the second surface may be removed, and on another hand, the O—H bonds may be formed on the first surface and the second surface to form hydrophilic surfaces.

The first surface of the first base 200 is bonded to the second surface of the second base 600. For example, in some embodiments, the first surface of the first base 200 is bonded to the second surface of the second base 600 at ambient temperature and pressure.

After the first surface of the first base 200 is bonded to the second surface of the second base 600, an annealing treatment is performed. The annealing treatment may change the O—H bonds of the first surface and the second surface into water to evaporate, thus implementing the bonding and connection between the first surface and the second surface. In some embodiments, an annealing temperature ranges from 100° C. to 250° C., thus avoiding adverse effects of high temperature on the semiconductor structure.

As an example, an embodiment of the disclosure also provides a bonding method. Specifically, referring to FIG. 18A to FIG. 18F, the operation of connecting the first base 200 and the second base 600 through the bonding process, includes the following operations.

First contact structures 800 are formed on the first surface of the first base 200. The first contact structures 800 are electrically connected with the second ends of the active areas 220, respectively. In the operation, a first contact layer is formed on the first surface of the first base 200. The first contact layer includes a first filling layer 801 and the first contact structures 800 disposed in the first filling layer 801. In some embodiments, the manner of forming the first contact layer includes the following operations. The first filling layer 801 is formed on the first surface. The first filling layer 801 is patterned. A conductive material is filled in pattern areas of the first filling layer 801 to form the first contact structures 800.

Second contact structures 810 are formed on the second surface of the second base 600. The second contact structures 810 are electrically connected with the bit lines 250. In the operation, the second contact layer is formed on the second surface of the second base 600. The second contact layer includes a second filling layer 811 and the second contact structures 810 disposed in the second filling layer 811. In some embodiments, a manner for forming the second contact layer includes the following operations. The second filling layer 811 is formed on the second surface. The second filling layer 811 is patterned. A conductive material is filled in pattern areas of the second filling layer 811 to form the second contact structures 810.

Bonding is performed with the first contact structures 800 and the second contact structures 810 as bonding structures. In an embodiment, in the operation, the first contact layer and the second contact layer are used as bonding layers. That is, the first filling layer 801 and the second filling layer 811 are also bonded as the bonding structures. The first filling layer 801 and the second filling layer 811 may filling a gap between the first surface and the second surface to provide support and seal.

In the manufacturing method according to the embodiments of the disclosure, after forming the charge storage structures, the bonding process is performed, thus avoiding the adverse effects of the high temperature and other processes on the bonding interfaces during forming the charge storage structures, and improving the reliability and the stability of the semiconductor structure.

It is to be understood that, in the formed semiconductor structure, in the periphery region PERI, along the third direction D3, the bit line connection structures 252 are misaligned with the word line connection structures 213 and the transistors where the peripheral gates 400 are located, so as to avoid the bit line connection structures 252 from being shielded by the word line connection structures 213 and the transistors where the peripheral gates 400 are located and facilitate electrically leading out the bit line connection structures 252 subsequently.

After the operation of connecting the first base 200 and the second base 600, the following operations are further included. Word line lead-out structures 700, bit line lead-out structures 701, and charge storage lead-out structures 702 are formed at a side of the first base 200 away from the second base 600. The word line lead-out structures 700 penetrate the first interlayer dielectric layer 360 and are electrically connected with the word lines 210. The bit line lead-out structures 701 penetrate the first interlayer dielectric layer 360 and the first base 200, and are electrically connected with the bit lines 250. The charge storage lead-out structures 702 penetrate the first interlayer dielectric layer 360 and are electrically connected with the charge storage structures 240. In an embodiment, the word line lead-out structures 700 are electrically connected with the word lines 210 through the word line connection structures, and the bit line lead-out structures 701 are electrically connected with the bit lines 250 through the bit line connection structures.

Specifically, in an embodiment, a method for forming the word line lead-out structures 700, the bit line lead-out structures 701, and the charge storage lead-out structures 702 further includes the following operations. Referring to FIG. 19A to FIG. 19F, FIG. 19A is a top view of a core region CORE of a semiconductor structure; FIG. 159B is a cross-sectional schematic view along a line A-A1 in FIG. 19A; FIG. 19C is a cross-sectional schematic view along a line B-B1 in FIG. 19A; FIG. 19D is a cross-sectional schematic view along a line C-C1 in FIG. 19A; FIG. 19E is a cross-sectional schematic view along a line E-E1 in FIG. 19A; and FIG. 19F is a cross-sectional schematic view of a periphery region PERI of the semiconductor structure. The third base 500 is removed. The word line lead-out structures 700, the bit line lead-out structures 701, and the charge storage lead-out structures 702 are formed in the side of the first base 200 away from the second base 600. The word line lead-out structures 700 are formed in the periphery region PERI, penetrate the first interlayer dielectric layer 360 and are electrically connected with the word line connection structures. The bit line lead-out structures 701 are formed in the periphery region PERI, penetrate the first interlayer dielectric layer 360 and the first base 200, and are electrically connected with the bit line connection structures. The charge storage lead-out structures 702 are formed in the core region CORE, penetrate the first interlayer dielectric layer 360 and are electrically connected with the charge storage structures 240.

In an embodiment, the third base 500 may be removed by a process such as laser cutting. After removing the third base 500, the first interlayer dielectric layer 360 is exposed. Vias may be formed by a photolithography and etching process. The silicon germanium layer 350 is exposed by the vias in the core region CORE, and the connecting pads 233 and the bit line connection structures 252 are exposed by the vias in the periphery region PERI. A conductive material is deposited in the vias to form the word line lead-out structures 700, the bit line lead-out structures 701, and the charge storage lead-out structures 702.

In an embodiment, in the core region CORE, the charge storage lead-out structures 702 are connected with the silicon germanium layer 350, and serve as electrical lead-out of the charge storage structures 240. In the periphery region PERI, the word line lead-out structures 700 are electrically connected with the word line connection structures 213 through the connecting pads 233 and the conductive plugs 232, and the bit line lead-out structures 701 are electrically connected with the bit line connection structures 252, therefore, electrical lead-out of the word lines 210 and the bit lines 250 is implemented. In some embodiments, there are also peripheral lead-out structures 703, which are electrically connected with the active areas 220 of the peripheral gates 400 to implement electrical lead-out of peripheral transistors.

The manufacturing method according to the embodiments of the disclosure can form the semiconductor structure, in which the bit lines 250 and the charge storage structures 240 are located on both sides of the word lines 210. On one hand, a situation that one side of the word lines 210 is overcrowded is avoided, a device density on the same side of the word lines 210 is reduced, and difficulty of a manufacturing process is reduced. On another hand, the bit lines 250 can be manufactured independently, thus avoiding adverse effects such as a destruction of a device structure caused by forming the word lines 210, the bit lines 250 and the charge storage structures 240 on a same base, and improving stability of the semiconductor structure.

The embodiments of the disclosure also provide a semiconductor structure manufactured by the above method. Referring to FIG. 2A to FIG. 19F, the semiconductor structure includes a first base 200, word lines 210, charge storage structures 240 and a second base 600.

The first base 200 includes a first substrate 201 and multiple active areas 220 disposed in the first substrate 201. The active areas 220 are arranged in an array along a first direction D1 and a second direction D2. In the embodiment, a surface of the first substrate 201 is also covered with a protective layer 203 for protecting the first substrate 201.

The word lines 210 are disposed in the first base 200, extend along the second direction D2 and cover at least opposite sides of each of the active areas 220. In an embodiment, the word lines 210 only cover the opposite sides of each of the active areas 220. In another embodiment, the word lines 210 surround the active areas 220 and form ring-gate structures.

In an embodiment, the multiple word lines 210 are arranged at intervals along the first direction D1. Both sides of each of the same active areas 220 are provided with the word lines 210 along the second direction D2. An active area 220 corresponding to the two word lines 210 serves as a channel region of a transistor. For example, referring to FIG. 6A to FIG. 6F, an area of the first substrate 201 surrounded by the word line 210A, the word line 210B, the isolation structure 202A and the isolation structure 202B is the active area 220. A word line 210A and a corresponding word line 210B together serve as gates of the corresponding active area 220. The active area 220 corresponding to the word line 210A and the word line 210B serve as a channel region of a transistor.

In an embodiment, a word line dielectric layer 212 is further provided between each of the active areas 220 and the corresponding one of the word lines 210 for insulating and isolating the word line 210 and the active area 220.

In an embodiment, two word lines 210 along the second direction D2 are provided between two adjacent active areas of the active areas 220, and a first isolation layer 214 is provided between the two word lines 210. The first isolation layer 214 is used for insulating and isolating the two word lines 210.

The charge storage structures 240 are disposed on the first base 200, and are electrically connected with first ends of the active areas 220, respectively. In an embodiment, the charge storage structure 240 is a capacitor structure and includes a lower electrode 241, a capacitor dielectric layer 242 covering a surface of the lower electrode 241, and an upper electrode 243 covering a surface of the capacitor dielectric layer 242.

In the embodiment, the charge storage structure 240 is electrically connected with the first end of the corresponding active area 220 through the corresponding capacitor connection structure 230. That is, one end of the capacitor connection structure 230 is electrically connected with the first end of the active area 220, and another end is electrically connected with the lower electrode 241 of the charge storage structure 240. The capacitor connection structure 230 includes a contact pad 231 electrically connected with the first end of the active area 220, a conductive plug 232 electrically connected with the contact pad 231, a connecting pad 233 electrically connected with the conductive plug 232. The connecting pad 233 is electrically connected with the lower electrode 241.

In the embodiment, the semiconductor structure further includes a silicon germanium layer 350 covering a surface of the charge storage structure 240. Specifically, the silicon germanium layer 350 covers a surface of the upper electrode 243.

The second base 600 is disposed on a surface of the first base 200 away from the charge storage structures 240. The second base 600 includes a second substrate 601 and multiple bit lines 250 arranged at intervals in the second substrate 601. The bit lines 250 extend along the first direction D1, and the bit lines 250 are electrically connected with second ends of the active areas 220. The multiple bit lines 250 are arranged at intervals along the second direction D2.

In an embodiment, the semiconductor structure further includes a second isolation layer 251 disposed between each of the bit lines 250 and the second substrate 601 to insulate and isolate the second substrate 601 from the bit line 250.

In an embodiment, referring to FIG. 18A to FIG. 18F, the first base 200 has a first surface having first contact structures 800. Each of the first contact structures 800 is electrically connected with a second end of an active area 220. The second base 600 has a second surface opposite the first surface. The second surface has second contact structures 810 electrically connected with the bit lines 250 and the first contact structures 800. That is, the active areas 220 and the bit lines 250 are electrically connected through the first contact structures 800 and the second contact structures 810. The first contact structures 800 and the second contact structures 810 are connected by bonding. Surfaces where the first contact structures contact the second contact structures are bonding interfaces.

In some embodiments, the semiconductor structure further includes a first filling layer 801 disposed on the first surface and a second filling layer 811 disposed on the second surface. The first contact structures 800 are disposed in the first filling layer 801. The second contact structures 810 are disposed in the second filling layer 811. The first filling layer 801 is connected with the second filling layer 811. That is, the first filling layer 801 and the second filling layer 811 may filling gaps between the first surface and the second surface to provide support and seal.

The semiconductor structure also includes word line connection structures 213, bit line connection structures 252, a first interlayer dielectric layer 360, word line lead-out structures 700, and bit line lead-out structures 701. The word line connection structures 213 are disposed in the first base 200 and electrically connected with the word lines 210. The bit line connection structures 252 are disposed in the second base 600 and are electrically connected with the bit lines 250. The first interlayer dielectric layer 360 covers the first base 200 and the charge storage structures 240. The word line lead-out structures 700 penetrate the first interlayer dielectric layer 360 and are electrically connected with the word line connection structures 213. The bit line lead-out structures 701 penetrate the first interlayer dielectric layer 360 and the first base 200, and are electrically connected with the bit line connection structures 252.

In some embodiments, the semiconductor structure includes a core region CORE and a periphery region PERI. The word lines 210, the bit lines 250 and the charge storage structures 240 are disposed in the core region CORE. The word line connection structures 213 and the bit line connection structures 252 are provided in the periphery region PERI.

The semiconductor structure also includes charge storage lead-out structures 702. The charge storage lead-out structures 702 penetrate the first interlayer dielectric layer 360 and are electrically connected with the charge storage structures 240. Specifically, in an embodiment, the charge storage lead-out structures 702 are electrically connected with the silicon germanium layer 350.

In the periphery region PERI, the semiconductor structure is also provided with peripheral transistors. Each of the peripheral transistors includes a peripheral gate 400 located on the surface of the first substrate 201 and a source area and a drain area located in the first substrate 201. Conductive plugs 232 are also provided in the periphery region PERI and are electrically connected with the source areas or the drain areas of the peripheral transistors. The connecting pads 233 are connected with the conductive plugs 232. The peripheral lead-out structures 703 are electrically connected with the connecting pads 233, that is, the peripheral lead-out structures 703 are electrically connected with the source areas or the drain areas of the peripheral transistor through the connecting pads 233 and the conductive plugs 232.

In the semiconductor structure according to the embodiments of the disclosure, the bit lines 250 and the charge storage structures 240 are disposed on both sides of the word lines 210, thereby greatly reducing the device density on the same side of the word lines 210 and providing stability of the semiconductor structure.

The above are only the preferred embodiments of the disclosure, and it should be noted that for those skilled in the art, without departing from the principles of the disclosure, several modifications and improvements may be made, which also fall within the scope of protection of the disclosures.

1. A method for manufacturing a semiconductor structure, comprising:
forming a first base, wherein the first base comprises a first substrate and active areas arranged in an array along a first direction and a second direction in the first substrate, word lines are disposed in the first base, and the word lines extend along the second direction and cover at least opposite sides of each of the active areas;
forming charge storage structures on the first base, wherein the charge storage structures are electrically connected with first ends of the active areas;
forming a second base, wherein the second base comprises a second substrate and bit lines disposed in the second substrate, the bit lines extend along the first direction; and
connecting the first base and the second base by using a first surface of the first base away from the charge storage structures and a second surface of the second base having structures of the bit lines as connection surfaces, wherein the bit lines are electrically connected with second ends of the active areas; and each of the first ends is disposed opposite to a corresponding one of the second ends.

2. The method for manufacturing the semiconductor structure of claim 1, wherein connecting the first base and the second base further comprises: connecting the first base and the second base through a bonding process.

3. The method for manufacturing the semiconductor structure of claim 2, wherein before connecting the first base and the second base, the method further comprises: thinning the first base to expose the second ends of the active areas.

4. The method for manufacturing the semiconductor structure of claim 2, wherein before performing the bonding process, the method further comprises: performing a plasma treatment on the first surface of the first base and the second surface of the second base.

5. The method for manufacturing the semiconductor structure of claim 4, wherein the operation of connecting the first base and the second base through the bonding process comprises:
performing a hydrophilic treatment on the first surface of the first base and the second surface of the second base;
bonding the first surface of the first base to the second surface of the second base; and
performing an annealing treatment.

6. The method for manufacturing the semiconductor structure of claim 2, wherein the operation of connecting the first base and the second base through the bonding process comprises:
forming first contact structures on the first surface of the first base, the first contact structures being electrically connected with the second ends of the active areas;
forming second contact structures on the second surface of the second base, the second contact structures being electrically connected with the bit lines; and
bonding by using the first contact structures and the second contact structures as bonding structures.

7. The method for manufacturing the semiconductor structure of claim 6, wherein the operation of forming the first contact structures on the first surface of the first base comprises: forming a first contact layer on the first surface of the first base, wherein the first contact layer comprises a first filling layer and the first contact structures disposed in the first filling layer;
the operation of forming the second contact structures on the second surface of the second base comprises:
forming a second contact layer on the second surface of the second base, wherein the second contact layer comprises a second filling layer and the second contact structures disposed in the second filling layer; and
the operation of bonding by using the first contact structures and the second contact structures as the bonding structures comprises: bonding by using the first contact layer and the second contact layer as bonding layers, wherein the first filling layer is bonded with the second filling layer, and the first contact structures are bonded with the second contact structures.

8. The method for manufacturing the semiconductor structure of claim 1, wherein after forming the charge storage structures, the method further comprises: forming a first interlayer dielectric layer which covers surfaces of the charge storage structures and a surface of the first base; and
after connecting the first base and the second base, the method further comprises: forming word line lead-out structures, bit line lead-out structures, and charge storage lead-out structures at a side of the first base away from the second base; wherein the word line lead-out structures penetrate the first interlayer dielectric layer and are electrically connected with the word lines, the bit line lead-out structures penetrate the first interlayer dielectric layer and the first base and are electrically connected with the bit lines, and the charge storage lead-out structures penetrate the first interlayer dielectric layer and are electrically connected with the charge storage structures.

9. The method for manufacturing the semiconductor structure of claim 8, wherein the semiconductor structure comprises a core region and a periphery region, the word lines, the bit lines and the charge storage structures are located in the core region; during the operation of forming the first base, word line connection structures are formed in the periphery region and are electrically connected with the word lines; during the operation of forming the second base, bit line connection structures are formed in the periphery region and are electrically connected with the bit lines; and during the operation of forming the word line lead-out structures, the bit line lead-out structures, and the charge storage lead-out structures at the side of the first base away from the second base, the word line lead-out structures are formed in the periphery region and are electrically connected with the word line connection structures, the bit line lead-out structures are formed in the periphery region and are electrically connected with the bit line connection structures, and the charge storage lead-out structures are formed in the core region.

10. The method for manufacturing the semiconductor structure of claim 8, wherein after forming the first interlayer dielectric layer, the method further comprises:
provide a third base; and
connecting the third base and the first base by using a surface of the first interlayer dielectric layer as a connection surface; and
wherein before forming the word line lead-out structures, the bit line lead-out structures, and the charge storage lead-out structures at the side of the first base away from the second base, the method further comprises: removing the third base.

11. The method for manufacturing the semiconductor structure of claim 1, wherein the operation of forming the word lines in the first base comprises:
forming word line trenches arranged at intervals in the first base;
filling a word line material in the word line trenches;
forming the word lines by removing part of the word line material and retaining at least the word line material on opposite sides of the active areas; and
forming a first isolation layer between two adjacent word lines of the word lines.

12. The method for manufacturing the semiconductor structure of claim 1, wherein before forming the charge storage structures on the first base, the method further comprises: forming capacitor connection structures on the first base, wherein the capacitor connection structures are electrically connected with the first ends of the active areas.

13. The method for manufacturing the semiconductor structure of claim 12, wherein the operation of forming the charge storage structures on the first base comprises:
forming a interlayer supporting layer;
forming capacitor holes which penetrate the interlayer supporting layer to the capacitor connection structures;
forming a lower electrode in each of the capacitor holes, wherein the lower electrode is connected with a corresponding one of the capacitor connection structures, and a sidewall of the lower electrode is spaced from a sidewall of the capacitor hole;
forming a capacitor dielectric layer on the sidewall of the lower electrode and the sidewall of the capacitor hole; and
forming an upper electrode, wherein the upper electrode covers a surface of the capacitor dielectric layer.

14. The method for manufacturing the semiconductor structure of claim 1, wherein the operation of forming the second base comprises:
forming bit line trenches in the second substrate;
forming a second isolation layer covering an inner wall of each of the bit line trenches in the bit line trenches; and
forming a bit line in each of the bit line trenches, wherein the second isolation layer is disposed between the bit line and the second substrate.

15. A semiconductor structure, comprising:
a first base, comprising a first substrate and active areas arranged in an array along a first direction and a second direction in the first substrate;
word lines, disposed in the first base, and extending along the second direction and covering at least opposite sides of each of the active areas;
charge storage structures, disposed on the first base, wherein the charge storage structures are electrically connected with first ends of the active areas; and
a second base, disposed on a surface of the first base away from the charge storage structures, wherein the second base comprises a second substrate and bit lines disposed in the second substrate, the bit lines extend along the first direction and are electrically connected with second ends of the active areas, and each of the first ends is disposed opposite to a corresponding one of the second ends.

16. The semiconductor structure of claim 15, wherein the first base has a first surface, and the first surface has first contact structures electrically connected with the second ends of the active areas; the second base has a second surface opposite the first surface, the second surface has second contact structures electrically connected with the bit lines and the first contact structures.

17. The semiconductor structure of claim 16, further comprising: a first filling layer disposed on the first surface and a second filling layer disposed on the second surface, wherein the first contact structures are disposed in the first filling layer, the second contact structures are disposed in the second filling layer, and the first filling layer is connected with the second filling layer.

18. The semiconductor structure of claim 15, further comprising:
word line connection structures, disposed in the first base and electrically connected with the word lines;
bit line connection structures, disposed in the second base and electrically connected with the bit lines;
a first interlayer dielectric layer, covering the first base and the charge storage structures;
word line lead-out structures, penetrating the first interlayer dielectric layer and electrically connected with the word line connection structures; and
bit line lead-out structures, penetrating the first interlayer dielectric layer and the first base, and electrically connected with the bit line connection structures.

19. The semiconductor structure of claim 18, further comprising: a core region and a periphery region, wherein the word lines and the bit lines are disposed in the core region, the word line connection structures and the bit line connection structures are disposed in the periphery region.

20. The semiconductor structure of claim 18, further comprising: charge storage lead-out structures, penetrating the first interlayer dielectric layer and electrically connected with the charge storage structures.
